(19) United States
(12) Patent Application Publication
(10) Pub. No.: US 2008/0247215 A1
(43) Pub. Date: Oct. 9, 2008

(54) RESISTIVE SWITCHING ELEMENT

(76) Inventor: Klaus Ufert, Unterschleissheim (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/695,688

(22) Filed: Apr. 3, 2007

(51) Int. Cl. G11C 11/00; H01C 10/00

(52) U.S. Cl. 365/148; 338/13

(57) ABSTRACT

According to one aspect, a switching element may comprise a first electrode, a second electrode, and a resistive switching region extending from the first electrode to the second electrode and comprising transition metal oxinitride.

Details of one or more implementations are set forth in the accompanying exemplary drawings and exemplary description below. Other features will be apparent from the description and drawings, and from the claims.

### BRIEF DESCRIPTION OF THE DRAWINGS

FIGS. 1A and 1B show a schematic of a first exemplary resistive switching element in a high resistivity state and a low resistivity state, respectively;

FIGS. 2A and 2B show a schematic of another exemplary resistive switching element in a high resistivity state and a low resistivity state, respectively;

FIG. 3 shows a current vs. voltage diagram demonstrating exemplary switching processes;

FIG. 4 shows a circuit diagram of an exemplary memory cell comprising a TMON switching element;

FIGS. 5A to 5G show an exemplary method of fabricating a switching element;

FIG. 6 shows a cross section of an exemplary memory device; and

FIG. 7 shows an exemplary computer system.

### DETAILED DESCRIPTION

In one aspect, an exemplary switching element for reversible switching between an electrically high resistive state and an electrically low resistive state is described. An electrical resistance ratio of the high resistive state with respect to the low resistive state may, for example, be at least 10. In another example, the ratio of the resistance in the high resistive state with respect to the low resistive state may be at least 100. In one aspect a switching element may be rapidly switchable, for example in the region of the switching times of conventional DRAM/SRAM memory cells or not more than a factor of 10 slower, for example. A switching element may comprise two electrode means and a switchable medium extending between the two electrode means, i.e. the switchable medium may connect one of the electrode means with the other one. In one example, the switchable medium may be arranged between the two electrode means.

In one aspect, the switchable medium may exhibit two different stable states, i.e. one high resistive state and one low resistive state, between which the switchable medium may be switched reversibly. In another example, the switchable medium may exhibit more than two stable states. Accordingly, the switchable medium may exhibit at least a high resistive state, a low resistive state and an intermediate resistive state, for example.

In one aspect this switching element may be implemented as a non-volatile memory cell, where each of the stable resistive states may represent a separate non-volatile storage status of the memory cell. Reading the stored information may be achieved by determining the resistance of the switchable medium without changing its resistive status, i.e. without deleting the information stored therein.

In one aspect, the switchable medium may comprise transition metal oxinitride material (TMOₓN_{y}), which may exhibit at least two different resistive states. Switching between these states may, for example occur in response to a current or voltage pulse applied to the transition metal oxinitride material via electrode means. In one aspect, the transition metal oxinitride comprises transition metal (TM) material that may form, together with nitrogen (N), at least one electrically conductive compound, i.e. the transition metal implemented in the switchable medium, in accordance with this aspect, may form an electrically conductive transition metal nitride, for example. The electrical resistivity of the transition metal nitride may be lower than the electrical resistivity of the applied transition metal oxinitride (TMOₓN_{y}).

In one aspect, the absolute content of oxygen and/or nitrogen in the transition metal oxinitride (TMOₓN_{y}) exemplarily applied as a switchable medium may depend on the oxidation state of the transition metal. The transition metal oxinitride may appear in a sub-stoichiometric composition, where less oxygen and/or nitrogen is present than in a stoichiometric composition. In one aspect an atomic content ratio between nitrogen and oxygen may be between y/x=0.5% and y/x=10%, for example. Nevertheless, other concentration of oxygen and/or nitrogen may also be applied.

When applying a sufficiently intense current or voltage pulse to the transition metal oxinitride via electrode means, for example, at least some of the metal-oxide bonds of the transition metal oxinitride may break due to the electric field caused by an applied voltage pulse or due to a heating caused by a current flow in the medium. Heating may, for example, occur locally. In one aspect, the transition metal oxinitride material applied for the switching medium may exhibit an atom or ion mobility within the medium that is higher for nitrogen atoms or ions than for metal atoms or ions, such as the atoms or ions of the transition metal applied for the transition metal oxinitride material. Accordingly, due to the higher mobility of nitrogen, broken metal-oxide bonds may be easier replaced by metal-nitride bonds than by metal-metal bonds. Due to a higher electrical conductivity in the vicinity of the metal-nitride as compared to the metal-oxide bonds, the resistivity of the medium decreased through the breakage of metal-oxide bonds and the formation of metal-nitride bonds. Accordingly, heating of the material through a current pulse or the electrical field caused by an applied voltage may, at least locally, decrease unless a more intense current or voltage pulse is applied.

Therefore, the transition metal oxinitride material may exhibit a self-stabilization at a state where some of the metal-oxide bonds are replaced by metal-nitride bonds causing a lower electrical resistance in their vicinity. This state may represent a non-volatile low resistivity state, or an “ON” state of the switching element, while the state having less metal-nitride bonds and more metal-oxide bonds may be regarded a non-volatile high resistivity state, or an “OFF” state of the switching element. A current or voltage pulse bringing the switching element from the “OFF” state to the “ON” state, as exemplarily described above, may be regarded as a “SET” pulse.

In one aspect in a low resistivity state the switchable medium may comprise an electrically conductive filament extending at least partly between the at least two electrode means. The electrically conductive filament may be rich of metal-nitrogen bonds, i.e. there may be a higher concentration of metal-nitrogen bonds in the electrically conductive filament than in the rest of the switchable medium. In one example the electrically conductive filament may extend continuously from one electrode means to the other electrode means. The electrically conductive filament may serve as a conductance channel between the electrode means, thereby causing the switchable medium to exhibit the “ON” state. In one exemplary aspect, the filament may be at least partly formed as an amorphous structure without a formation of crystalline zones.

When starting from a low resistivity state, i.e. an “ON” state, and applying a current or voltage pulse having sufficient energy an electrically conductive filament may be electrically or thermally destroyed and the switchable medium may return to its initial high resistivity state, i.e. an “OFF” state of the switching element. Such a current or voltage pulse may be regarded as a “RESET” pulse. Due to the higher mobility of nitrogen within the transition metal nitrite material applied as switchable medium as compared to the mobility of metal atoms or ions, and since the binding energy between metal atoms and nitrogen atoms within a specific standard volume (e.g. microcluster, nanocluster) may be lower than binding energies between two metal atoms, the maximum current or voltage for a “RESET” pulse of a switching element comprising transition metal oxinitride as a switchable medium may be lower than for other switchable mediums forming metal-metal bonds in an “ON” state, for example.

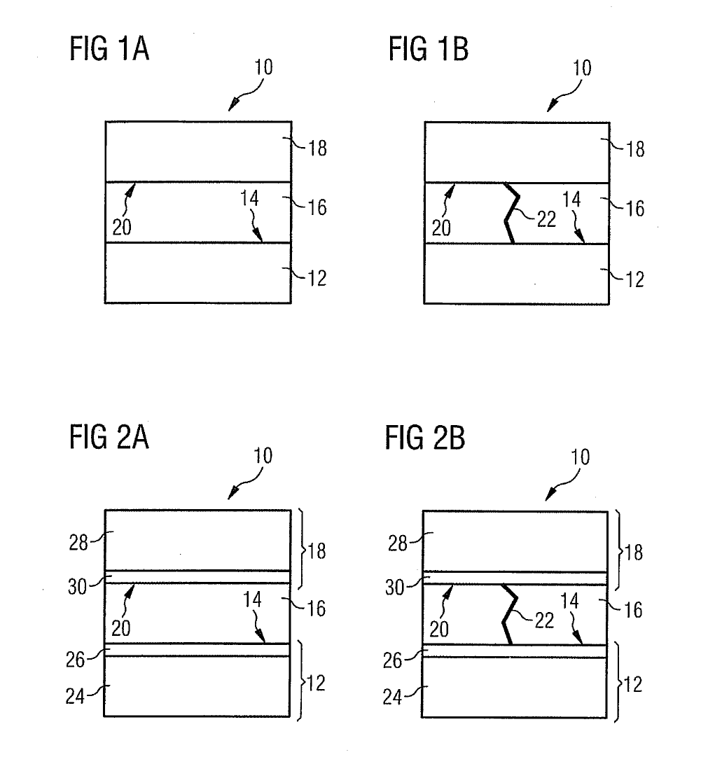

A first example of a resistive switching element which may be implemented as a non-volatile memory cell is described in connection with FIG. 1A and FIG. 1B in the following. In this example, a resistive switching element 10 may comprise a first (bottom) electrode 12 having a substantially planar first contact surface or first contact interface 14. Via the first contact interface 14 the first electrode 12 is connected to a switching region which is formed as a switching layer 16, in the shown example. A second (top) electrode 18 is electrically connected to the switching layer via a substantially planar second contact interface 20. In the shown example, the first contact interface 14 is substantially parallel to the second contact interface 20. Accordingly, the switching layer 16 has a substantially constant layer thickness in a direction perpendicular to the contact interfaces 14, 20. In one aspect, this layer thickness may be between about 10 nm and about 100 nm or between about 20 nm and about 100 nm. An exemplary layer thickness may be about 60 nm. Nevertheless, in other examples a layer thickness of more than 100 nm or less than 20 nm or even less than 10 nm may be applied. Moreover, it is not required that the switching region has a constant layer thickness or that contact interfaces are planar. In another example, not shown in the figures, at least one of the first electrode 12 and second electrode 18 may be electrically connected to the switching region 16 via a non-planar contact interface or via a point contact, for example.

In one aspect, the switching region 16 may comprise a transition metal oxinitride TMOₓN_{y}, such as NbOₓN_{y} or TaOₓN_{y}, for example. In a high resistive state, the transition metal oxinitride may be substantially homogeneous, for example. Such a high resistivity state, according to one example, is schematically demonstrated in FIG. 1A. When applying a current or voltage pulse between the first electrode 12 and the second electrode 18, for example, at least some of the metal-oxide bonds within the transition metal oxinitride comprised in the switching layer 16 may break and metal-nitride bonds may form instead.

In one aspect, a switching element for switching between at least two states having different electric resistance may comprise a first electrode, a second electrode, and a resistive switching region that may extend from the first electrode to the second electrode and that may comprise a transition metal oxinitride (TMOₓN_{y}). In another aspect, a memory device may comprise at least one non-volatile resistive memory cell. The memory cell may, for example, comprise a first electrode, a second electrode, and a resistive storage region extending from the first electrode to the second electrode. In one aspect, the resistive storage region may comprise a transition metal oxinitride material (TMOₓN_{y}).

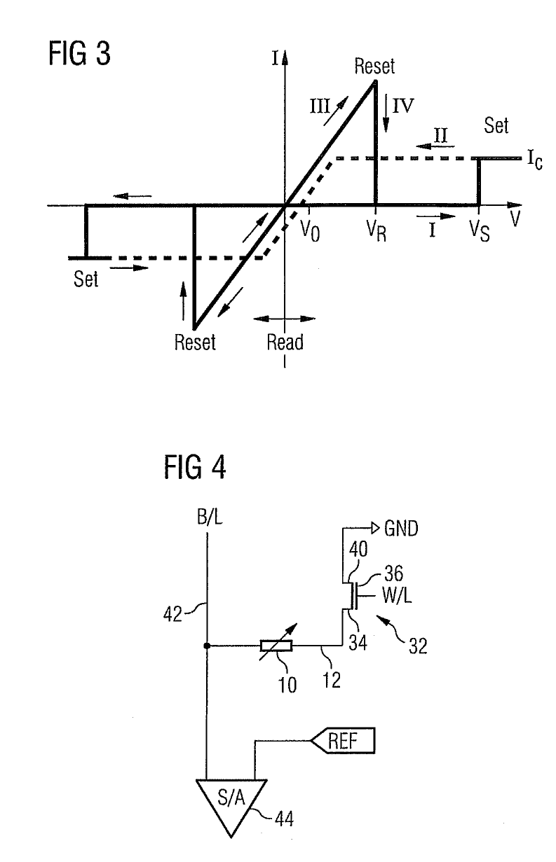

FIG. 3 represents an exemplary current versus voltage diagram (I-V) for such an exemplary “SET” pulse. At the beginning, the switching device has a high resistivity, i.e. it is in its “OFF” state. When increasing the voltage V in phase I, the current (I) does not significantly increase unless the voltage (V) reaches a “SET” voltage Vs. In one aspect, at the “SET” voltage Vs metal-oxide bonds may break and may be replaced by metal-nitrogen bonds, thereby increasing a conductivity of the switching element. In order to avoid damage of the switching element caused by a high current starting to flow when the switching element is set “ON” during phase I of the “SET” pulse, a current compliance may be set to a maximum current value of I_{C}. In one aspect, at the voltage Vs an electrically conductive filament 22, as shown in FIG. 1B may form, where the electrically conductive filament 22 may represent a region with a high density of metal-nitrogen bonds. The current compliance I_{C} may, particularly, prevent an instantaneous destruction of the electrically conductive filament 22 when it is formed in phase I. Accordingly, even when reducing the voltage in phase II of the “SET” pulse shown in FIG. 3, the electrically conductive filament 22 remains stable and keeps the switching element 10 in its “ON” state.

In order to reset the switching element 10 into its “OFF” state, a “RESET” pulse may be applied between the first electrode 12 and the second electrode 18. In one example shown in FIG. 3, during the “RESET” pulse no current compliance is applied. Accordingly, when increasing the voltage in phase III of the “RESET” pulse shown in FIG. 3, the current increases with a high slope in the I-V-diagram corresponding to the low resistance of the switching element in its “ON” state. In particular, the current may exceed the value of the current compliance I_{C} set during the “SET” pulse. The current may linearly increase until the voltage reaches a critical value V_{R}, where the energy or the power applied to the electrically conductive filament 22 is high enough to at least partly destroy the metal-nitrogen bonds within the filament 22. As a result, the switching element switches back to its high resistivity state and the current may suddenly decrease in phase IV of the “RESET” pulse. The “RESET” pulse, therefore, may be completed and the voltage (V) may be returned to zero. The switching element 10 may be repeatedly switched between the states shown in FIG. 1A and FIG. 1B. In this aspect, the switchable medium may be bistable, i.e. the switchable medium may exhibit at least two stable states, for example, having different electrical conductivity.

As shown in FIG. 3, in one example the “SET” pulse and the “RESET” pulse may be applied in both directions, i.e. positive or negative voltage bias may be applied. For reading the stored data, a positive and/or negative read voltage V_{O} may be applied that is smaller that both the set voltage Vs and the reset voltage V_{R}.

In one aspect a method of storing information may comprise providing a storage region, such as the switching region 16 shown in FIG. 1A, for example, comprising a transition metal oxinitride material. The method may further comprise forming at least one electrically conductive filament in the storage region, such as the conductive filament 22 shown in FIG. 1B, for example. Forming the electrically conductive filament may comprise applying a first current or voltage pulse to the storage region, such as the “SET” pulse illustrated in phase I of FIG. 3, for example.

In one aspect, forming the at least one electrically conductive filament may comprise thermally or electrically breaking metal-oxide bonds and forming metal-nitrogen bonds in the transition metal oxinitride material. Applying the first current or voltage pulse may, for example, comprise the application of a current compliance to the pulse applied to the storage region. The first current or voltage pulse may be, for example, applied via at least one first electrode, such as the first electrode 12 shown in FIG. 1A, for example, and at least one second electrode, such as the second electrode 18 shown in FIG. 1A, for example. These electrodes may be electrically connected to the storage region. Forming the at least one electrically conductive filament may comprise forming the electrically conductive filament so as to substantially extend from the first electrode to the second electrode, as exemplarily shown in FIG. 1B. In one aspect, through the formation of the at least one electrically conductive filament the electrical resistance of the storage region between the first and the second electrode may be decreased by a factor of at least 10. The conductance of the storage region may represent the stored information.

In a further aspect, a method may comprise reducing the electrical conductance of the electrically conducting filament by applying a second current or voltage pulse, such as the “RESET” pulse in phase III of FIG. 3, for example, to the storage region. In one aspect, reducing the electrical conductance of the electrically conducting filament may comprise thermally or electrically breaking metal-nitride bonds in the electrically conducting filament through the application of the second current of voltage pulse. Exemplarily, the second current or voltage pulse supplies more energy to the storage region than the first current or voltage pulse. In one example, reducing the electrical conductance of the electrically conducting filament increases the electrical resistance of the storage region between a first and a second electrode connected to the storage region by a factor of at least 10. The reduced conductance of the storage region may represent a different stored information than the state having an increase electrical conductance.

In another aspect, exemplarily shown in FIG. 2A and FIG. 2B, the first electrode 12 may comprise a first contact region 24 and an electrically conductive first diffusion barrier 26 disposed between the first contact region 24 and the resistive switching region 16. Further, the second electrode 18 may comprise a second contact region 28 and an electrically conductive second diffusion barrier 30 disposed between the second contact region 28 and the resistive switching region 16. The diffusion barriers may form diffusion barrier layers 26, 30 having a substantially constant layer thickness in a direction perpendicular to the contact interfaces 14, 20. In one aspect, the first and second contact regions of contacts comprise material having a metallic electrical conductance, which does not necessarily require that the first and second contact regions or contacts comprise metal atoms or ions. In one example, doped semiconductor material may be applied for the first and/or second contact region.

In one aspect, the diffusion barrier layers 26, 30 may prevent diffusion of metal ions from the contact regions 24, 28 into the resistive switching layer 16. In another aspect, the diffusion barrier layers 26, 30 may prevent diffusion of nitrogen from the resistive switching layer 16 into the contact regions 24, 28. In yet another aspect, the diffusion barrier layers 26, 30 may comprise material having a lower thermal conductivity than the contact regions 24, 28. Accordingly, in this aspect the diffusion barrier layers 26, 30 may prevent heat diffusion from the resistive switching layer 16 into the contact regions 24, 28 and may thereby serve for keeping the required pulse energies for a “SET” pulse and a “RESET” pulse small.

Analogous to the examples described in connection with FIG. 1A and FIG. 1B, FIG. 2A represents an “OFF” state of the switching element 10, according to the second example, while FIG. 2B represents an “ON” state of the switching element 10. Switching between the “ON” and the “OFF” state may be performed analogous to the examples described with reference to FIG. 1A, 1B and FIG. 3.

According to one example, the first diffusion barrier layer 26 and/or the second diffusion barrier layer 30 may comprise an electrically conductive transition metal nitride (TMN), such as niobium nitride (NbN) or titanium nitride (TiN), for example. In one aspect, a transition metal comprised in at least one of the diffusion barrier layers may be the same transition metal as that comprised in the switching layer 16. For example, the switching layer 16 may comprise niobium oxinitride (NbOₓN_{y}), while the diffusion barrier layer may comprise niobium nitride (NbN), for example. Nevertheless, the shown examples are not limited to such materials for the diffusion barrier layer and, instead, other electrically conductive material may be applied for the first and/or the second diffusion barrier layer.

In one aspect, the first and/or the second diffusion barrier layer may have a layer thickness between 10 nm and 50 nm, for example. In one example the diffusion barrier layers may be about 20 nm. Nevertheless, in other examples a layer thickness of more than 50 nm or less than 10 nm may be applied for the first and/or the second diffusion barrier layer.

In a further aspect, a memory device is provided which, in one example, may comprise at least one resistive switching element 10 as a non-volatile memory cell. One of the exemplary switching elements described with reference to FIGS. 1 and 2 may serve as a part of such a non-volatile memory cell, for example. In this aspect the resistive switching region 16 may represent a storage region of the non-volatile memory cell. All details and variations described in connection with the exemplary resistive switching elements, above, may also apply to a non-volatile memory cell according to this additional aspect.

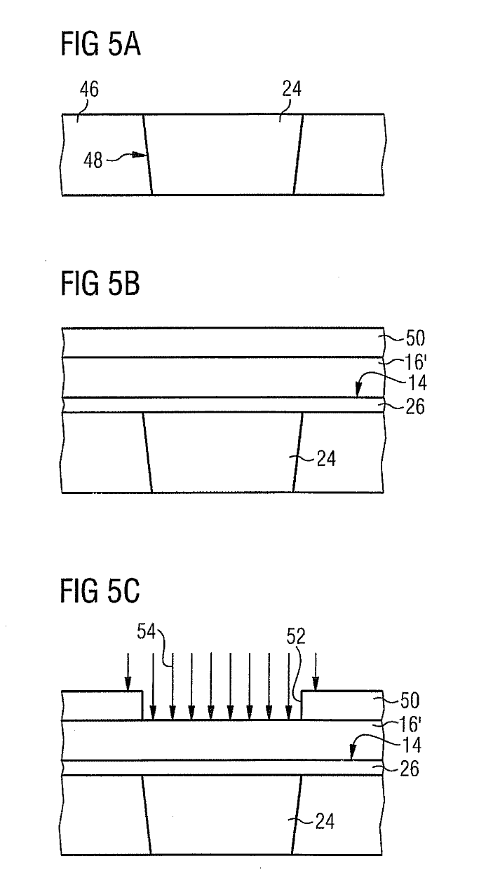

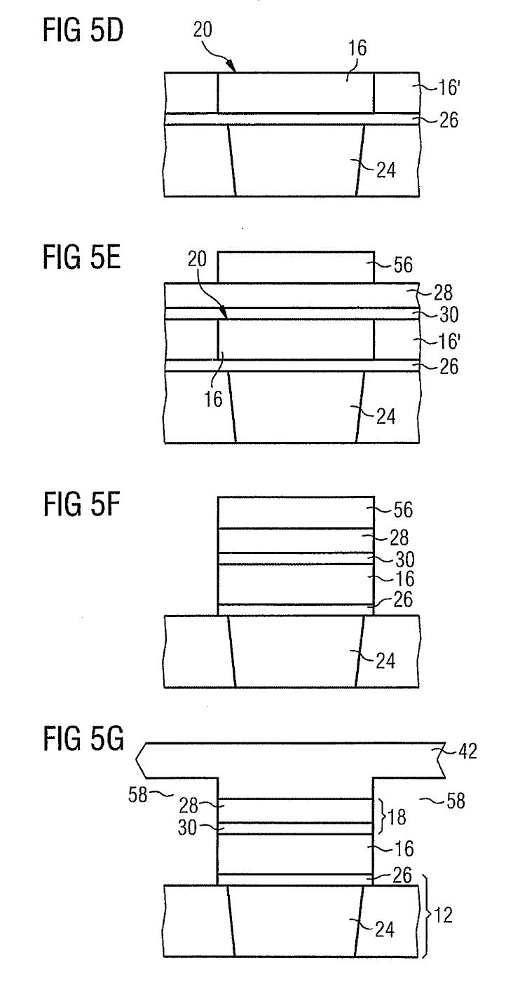

In one aspect an integrated circuit may comprise a switching element for switching between at least two states having different electric resistance. The switching element may comprise a first electrode, a second electrode, and a resistive switching region extending from the first electrode to the second electrode and comprising a transition metal oxinitride. The switching element may be a switch that is switchable between at least two states having different electric resistance. In an exemplary integrated circuit this switch may be implemented in accordance with one of the switching elements 10 described in connection with FIGS. 1 and 2, above, or with FIG. 5, below. Nevertheless, the integrated circuit is not limited to the particular examples shown above. Instead, other geometry of the first and second electrode or the switching region may be applied. Moreover, other materials may be applied in the switch of the integrated circuit. In one aspect a memory module may comprise a multiplicity of integrated circuits. Said integrated circuits may comprise one or more memory cells as described herein, for example. In one particular example the memory module is stackable.

FIG. 4 shows an exemplary circuit diagram of a memory cell comprising a resistive switching element 10, according to one aspect, where the resistive switching element 10 may comprise a transition metal oxinitride (TMOₓN_{y}) as switchable medium. Further to the resistive switching element 10, the memory cell as shown in FIG. 4 may comprise a select transistor 32 having a drain region 34 which is electrically connected to the first electrode 12 of the resistive switching element 10. A gate region 36 of the select transistor 32 may be electrically connected to a word line 38 of an exemplary memory cell. In the shown example, a source region 40 of the select transistor 32 may be electrically grounded. In one aspect, the second electrode 18 of the resistive switching element 10 may be electrically connected to a bit line 42.

When opening a channel of the select transistor 32 by applying an appropriate voltage to the word line 38, the first electrode 12 of the switching element 10 is grounded and a sense amplifier 44 connected to the bit line 42 may detect a resistance value of the switching element 10. In one aspect, the sense amplifier 44 may at least distinguish between a high resistivity state and a low resistivity state of the switching element 10. This detection may represent a reading operation of the information stored in the memory cell.

According to one example shown in FIG. 4, the select transistor 32 may be a field effect transistor. The first electrode 12 may, for example, be directly connected to the drain region 34 of the select transistor 32. In another example, a contact hole, such as an electrically conductive via, may provide an interposed interconnection between the first electrode 12 and the drain region 34 of the select transistor 32. Nevertheless, a memory cell is not limited to the exemplary circuit as shown in FIG. 4.

In one aspect, a memory device may comprise a plurality of non-volatile memory cells being arranged in rows and columns of at least one array. At least some of the memory cells may comprise a first (bottom) electrode 12, a second (top) electrode 18, a resistive storage layer 16, and a select transistor 32. Analogous to exemplary switching elements described above, the resistive storage layer 16 may be disposed between the first (bottom) electrode 12 and the second (top) electrode. In one aspect, the resistive storage layer may comprise transition metal oxinitride material (TMOₓN_{y}). The select transistor 32 for at least some of the non-volatile memory cells may comprise a drain region 34 that is electrically connected to the respective first electrode 12. In one aspect, the memory device may comprise for each row of the at least one array an electrically conductive word line 38 which is electrically connected to at least some gate contacts 36 of the select transistors 32 of the memory cells in the respective row. Furthermore, the memory device may comprise for each column of the at least one array an electrically conductive bit line 42 which is electrically connected to at least some of the second electrodes 18 of the memory cells in said column.

In another aspect an electronic device, such as a computer (e.g. a mobile computer), a mobile phone, a pocket PC, a smart phone, a PDA, for example, or any kind of consumer electronic device, such as a TV, a radio, or any house hold electronic device, for example, may comprise one or more memory cells comprising a first electrode, a second electrode, and a resistive storage region extending from the first electrode to the second electrode and comprising transition metal oxinitride. In one aspect the resistive storage region may comprise at least one of niobium oxinitride (NbOₓN_{y}) and tantalum oxinitride (TaOₓN_{y}).

In a further aspect, a method of fabricating the resistive memory device is described with reference to FIGS. 5A to 5G. In one aspect, a method of fabricating a resistive memory device may comprise providing a first electrode having a first contact interface; arranging a transition metal oxinitride TMOₓN_{y} layer at the first contact interface, where the transition metal oxinitride layer forms a second contact interface; and arranging a second electrode at the second contact interface.

As shown in FIG. 5A, a through hole 48 may be provided in an inter-metal dielectric layer (IMD) 46 applying lithographic techniques, for example. This through hole 48 may be at least partly filled with the first electrode 12. According to one particular example as shown in FIG. 5A, the through hole 48 may be filled with the first contact region 24. In one example, the first contact region 24 may be formed by a tungsten plug (W plug). In other examples, other electrically conductive material may be applied. In one example, providing a first electrode may comprise electrically connecting said first electrode to a source and/or drain region (source/drain region) of a select transistor.

In a further exemplary step, as shown in FIG. 5B, the first diffusion barrier layer 26, a resistive switching region preparation layer 16′, and a lithographic hard mask 50 may be subsequently deposited on the first contact region 24. Accordingly, in one aspect providing the first electrode 12 may comprise depositing the electrically conductive first diffusion barrier 26 on the first contact region 24. The first diffusion barrier 26 may form the first contact interface 14. In one example, the first diffusion barrier layer 26 may comprise niobium nitride, which may be fabricated by reactive DC magnetron sputtering from a niobium target at an exemplary temperature of about 250° C. to 300° C., an exemplary sputter power density of about 2.5 to 3 W/cm², and at an exemplary pressure of 3·10⁻³ to 4·10⁻³ mbar. The percentage of nitrogen in the argon sputter gas may be about 35% to 40%, for example. In one aspect, the resistive switching region preparation layer 16′ may comprise a transition metal oxide material, such as niobium oxide (Nb₂O₅) or tantalum oxide (Ta₂O₅), for example. A niobium oxide layer according to one example may be fabricated using reactive DC magnetron sputtering from a niobium target at an exemplary temperature of about 250° C. and with an exemplary oxygen percentage of about 40% in the sputter gas. The lithographic hard mask layer 50 may comprise silicon nitride (such as Si₃N₄), for example.

In a further exemplary step, as shown in FIG. 5C, an implantation window 52 may be opened in the lithographic hard mask 50. The implantation window 52 may be structured by reactive ion etching, for example. In a next exemplary step, ion implantation 54 may be applied to the device. In one aspect, nitrogen ion implantation may be applied at an exemplary ion energy of about 50 keV and an exemplary flux of about 10¹⁶ cm⁻². The device may then be annealed in an inert atmosphere comprising nitrogen gas, for example. In one aspect, this may lead to the formation of a transition metal oxinitride within the resistive switching region preparation layer 16′ at least in a region below the implantation window 52, i.e. where ions have been implanted. This transition metal oxinitride may form at least in part the resistive switching region 16, as shown in FIG. 5D, for example. In case of a niobium oxide material used for the resistive switching region preparation layer 16′, the resulting resistive switching region may comprise niobium oxinitride.

Accordingly, in one aspect arranging the transition metal oxinitride layer, such as the exemplary switching layer or switching region 16 shown in FIG. 5D, may comprise depositing the transition metal oxide, such as the exemplary resistive switching region preparation layer 16′ shown in FIG. 5C, at the first contact interface 14. It may further comprise implanting nitrogen ions 54 in the transition metal oxide and annealing the nitrogen implanted transition metal oxide to achieve a transition metal oxinitride, such as the exemplary resistive switching region 16 shown in FIG. 5D. Before or after annealing the lithographic hard mask 50 may be removed. In case of silicon nitride used as material for the lithographic hard mask 50, it may be removed with hot phosphoric acid, for example.

In one aspect shown in FIG. 5E, the second diffusion barrier 30 and the second contact region 28 may be deposited as a layered structure on top of the resistive switching region preparation layer 16′ and the resistive switching region 16, i.e. at the second contact interface 20 in further exemplary growth steps. Accordingly, in one aspect arranging the second electrode 18 may comprise depositing the electrically conductive second diffusion barrier 30 at the second contact interface 20 and depositing the second contact region 28 on the second diffusion barrier 30. The second diffusion barrier layer 30 may comprise niobium nitride, for example, and may be fabricated by reactive DC magnetron sputtering from a niobium target similar to the first diffusion barrier, for example. The second contact region 28 may comprise platinum and may be fabricated by DC magnetron sputtering, for example. Subsequently, a memory stack etch mask 56 made of silicon nitride, for example, may be deposited by low pressure chemical vapor deposition (LPCVD), for example, and structured on top of the second contact region 28. The memory stack etch mask 56 may serve as a hard mask for structuring of a memory stack by reactive ion etching of the not covered layer sequence as exemplarily shown in FIG. 5F.

In subsequent exemplary steps shown in FIG. 5G, an intermediate isolation layer 58 made of silicon oxide (such as SiO₂), for example, may be fabricated by chemical vapor deposition (CVD) and subsequent chemical-mechanical polishing (CMP). After removal of the memory stack etch mask 56, the second contact region 28 may be electrically connected via the bit line 42, as exemplarily shown in FIG. 5G.

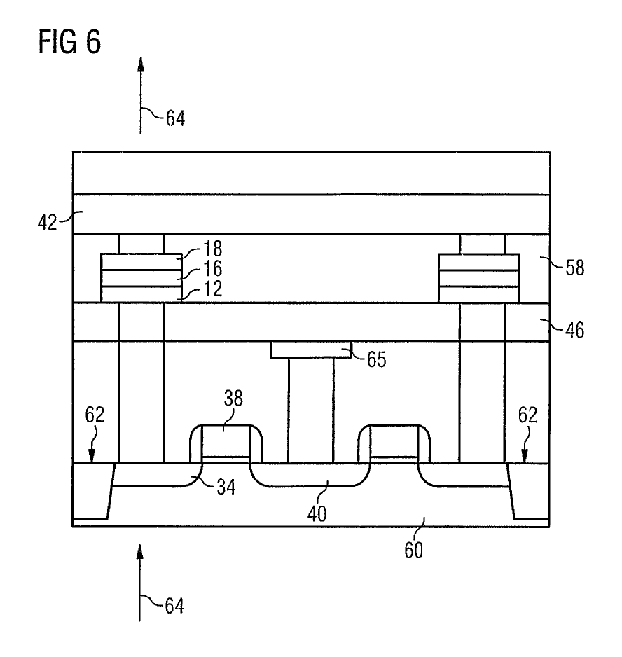

FIG. 6 shows a cross section of an exemplary memory device comprising a plurality of memory cells that may be arranged in at least one array. Said memory device may be implemented as a memory module. In one example the memory module may be stackable. In one aspect a memory cell of one of the FIGS. 1, 2 and 5 and according to the exemplary circuit of FIG. 4 may be implemented. In the example shown in FIG. 6, the transistor 32, such as a field effect transistor, may be implemented in or on a semiconductor substrate 60, such as a silicon on insulator (SOI), for example. The substrate 60 may comprise a substrate surface 62 and a substrate normal direction 64. The first electrode 12 is electrically connected to the drain region 34 of the transistor 32, while the source region 40 is electrically grounded via a ground line 65. The transistor gate is controlled by the word line 38 which may connect a plurality of transistor gates within the same row. The bit line 42 is electrically connected to the second electrode 18 and may connect a plurality of memory cells or switching elements within the same column of the at least one array. Insulation layers such as the inter-metal dielectric 46 or the intermediate isolation layer 58 similar to the examples described above may also be applied in the example of FIG. 6. In one aspect as exemplarily shown in FIG. 6, the resistive storage layer 16 is at least partly positioned above the drain region 34 in the substrate normal direction 64. In one example, the contact interfaces 14, 20 may be perpendicular to the substrate normal direction, i.e. the switching layer may be substantially parallel to the substrate surface.

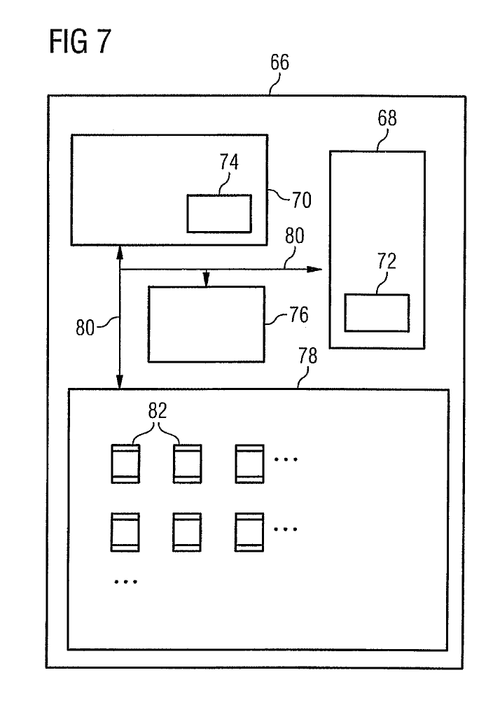

In yet another aspect exemplarily shown in FIG. 7, a computer system 66 such as a computer (e.g. a mobile computer or a server), a mobile phone, a pocket PC, a smart phone or a PDA, for example, may comprise an input apparatus 68 and an output apparatus 70. In another aspect the computer system may be implemented as any other kind of consumer electronic device, such as a TV, a radio, or any house hold electronic device, for example, or any kind of storage device, such as a chip card or memory card, for example.

In one example the input apparatus 68 may comprise input keys, a keyboard, a touch screen, a track ball a computer mouse, a joystick or any other kind of input device or input interface. In a further example, the input apparatus 68 comprises an audio input such as microphone. In yet another example, the input apparatus 68 may comprise a video input such as a camera. In the exemplary computer system 66 of FIG. 7, the input apparatus 68 comprises a wireless communication apparatus 72. The wireless communication apparatus 72 may comprise a network interface connecting the computer system 66 to a wireless network such as a local area network (LAN), a wide area network (WAN), or a telecommunications network, for example. Any type of uni-, bi-, or multi-directional wireless communication may be applied in this connection. In another aspect the input apparatus 68 may comprise a network interface connecting the computer system 66 to a wired network.

In one example, the output apparatus 70 may comprise a video output such as a display interface or a display device. In another example, the output apparatus 70 may comprise an audio device such as a speaker. In the exemplary computer system 66 of FIG. 7, the output apparatus 70 comprises a wireless communication apparatus 74. Said wireless communication apparatus 74 of the output apparatus 70 may comprise a network interface connecting the computer system 66 to a wireless network such as a local area network (LAN), a wide area network (WAN), or a telecommunications network, for example. Any type of uni-, bi-, or multi-directional wireless communication may be applied in this connection. In another aspect the output apparatus 70 may comprise a network interface connecting the computer system 66 to a wired network.

The exemplary computer system 66 of FIG. 7 further comprises a processing apparatus 76 and one or more memory components or memories 78. In one particular example, the computer system 66 may further comprise a system bus 80 that couples various system components including the memory 78 to the processing apparatus 76. The processing apparatus 76 may perform arithmetic, logic and/or control operations by accessing the memory 78, for example. The memory 78 may store information and/or instructions for use in combination with the processing apparatus 76. In one example, a basic input/output system (BIOS) storing the basic routines that helps to transfer information between elements within the computer system 66, such as during start-up, may be stored in the memory 78. The system bus 80 may be any of several types of bus structures including a memory bus or memory controller, a peripheral bus, and a local bus using any of a variety of bus architectures.

The memory 78 may comprise one or more memory cells 82. At least some of the memory cells 82 may comprise a first electrode, a second electrode and a resistive storage region extending from the first electrode to the second electrode and comprising transition metal oxinitride. In one example, one or more of the above described memory cells or one or more of the above described integrated circuits may be applied as one or more of the memory cells 82 of the memory 78. Moreover, one or more of the above described memory modules may be applied as the memory 78, for example. In one exemplary computer system 66, the memory 78 may comprise a data memory. In another example, the memory 78 may comprise a code memory. In one exemplary aspect, the memory 78 may be implemented as a data memory for storing computer readable instructions, data structures, program modules and/or other data for the operation of the computer system 66. In another aspect, the memory 78 may be implemented as a graphical memory or an input/output buffer. In one aspect the memory 78 is fixedly connected to the system bus 80 of the computer system 66. In another aspect, the memory 78 is implemented as a removable component, such as a memory card or chip card, for example.

A number of examples and implementations have been described. Other examples and implementations may, in particular, comprise one or more of the above features. Nevertheless, it will be understood that various modifications may be made. Accordingly, other implementations are within the scope of the following claims.

What is claimed is:

1. An integrated circuit comprising a switching element for switching between at least two states having different electric resistance, comprising:
a first electrode;
a second electrode; and
a resistive switching region extending from the first electrode to the second electrode and comprising a transition metal oxinitride.

2. The integrated circuit of claim 1, wherein the resistive switching region comprises a resistive switching layer having a first planar contact interface contacting the first electrode and a second planar contact interface being substantially parallel to the first contact interface and contacting the second electrode.

3. The integrated circuit of claim 2, wherein the resistive switching layer has a thickness between 20 nm and 100 nm in a direction perpendicular to the first and second contact interfaces.

4. The integrated circuit of claim 1, wherein the resistive switching layer comprises at least one of NbOₓN_{y} and TaOₓN_{y}.

5. The integrated circuit of claim 1, wherein the first electrode comprises a first contact region and an electrically conductive first diffusion barrier disposed between the first contact region and the resistive switching region.

6. The integrated circuit of claim 5, wherein the second electrode comprises a second contact region and an electrically conductive second diffusion barrier disposed between the second contact region and the resistive switching region.

7. The integrated circuit of claim 6, wherein at least one of the first and second diffusion barrier comprises an electrically conductive transition metal nitride.

8. The integrated circuit of claim 6, wherein at least one of the first and second diffusion barrier has a layer thickness between 10 nm and 50 nm.

9. A memory device comprising at least one memory cell, comprising:
a first electrode;
a second electrode; and
a resistive storage region extending from the first electrode to the second electrode and comprising transition metal oxinitride.

10. The memory device of claim 9, wherein the resistive storage region comprises a resistive storage layer having a first planar contact interface contacting the first electrode and a second planar contact interface contacting the second electrode, where the second contact interface is substantially parallel to the first contact interface.

11. The memory device of claim 9, comprising a select transistor having a source/drain region that is electrically connected to the first electrode.

12. The memory device of claim 9, comprising a plurality of memory cells being arranged in rows and columns of at least one array, wherein each memory cell comprises
a first electrode;
a second electrode;
a resistive storage layer disposed between the first electrode and the second electrode and comprising transition metal oxinitride; and
a select transistor having a source/drain region that is electrically connected to the first electrode; and
wherein the memory device comprises for each row of the at least one array an electrically conductive word line which is electrically connected to at least some gate contacts of the select transistors of the memory cells in the respective row and for each column of the at least one array an electrically conductive bit line which is electrically connected to at least some of the second electrodes of the memory cells in said column.

13. The memory device of claim 12, wherein the memory cells are arranged on a semiconductor substrate having a substrate normal direction, and wherein for at least some of the memory cells the resistive storage layer is at least partly disposed above the source/drain region in substrate normal direction.

14. A memory module comprising a multiplicity of integrated circuits, wherein said integrated circuits comprise one or more memory cells comprising:
a first electrode;
a second electrode; and
a resistive storage region extending from the first electrode to the second electrode and comprising transition metal oxinitride.

15. The memory module of claim 14, where the resistive storage region comprises at least one of niobium oxinitride and tantalum oxinitride.

16. The memory module of claim 14, wherein the memory module is stackable.

17. A computer system comprising an input apparatus, an output apparatus, a processing apparatus and a memory, said memory comprising
a first electrode;
a second electrode; and
a resistive storage region extending from the first electrode to the second electrode and comprising transition metal oxinitride.

18. The computer system of claim 17, wherein one or more of the input apparatus and output apparatus comprises a wireless communication apparatus.

19. The computer system of claim 17, wherein the computer system is a server.

20. The computer system of claim 17, wherein the computer system is a mobile computer.

21. A method of fabricating a resistive memory device, the method comprising:
providing a first electrode having a first contact interface;
arranging a transition metal oxinitride layer at the first contact interface, where the transition metal oxinitride layer forms a second contact interface; and
arranging a second electrode at the second contact interface.

22. The method of claim 21, wherein providing a first electrode comprises electrically connecting said first electrode to a source/drain region of a select transistor.

23. The method of claim 21, wherein providing said first electrode comprises depositing an electrically conductive first diffusion barrier on a first contact region, the first diffusion barrier forming said first contact interface, and wherein arranging said second electrode comprises depositing a electrically conductive second diffusion barrier at the second contact interface and depositing a second contact region on the second diffusion barrier.

24. The method of claim 21, wherein arranging said transition metal oxinitride layer comprises:
depositing a transition metal oxide at the first contact interface;
implanting nitrogen ions in the transition metal oxide; and
annealing the nitrogen implanted transition metal oxide to achieve a transition metal oxinitride.

25. A method of storing information, the method comprising:
providing a storage region comprising a transition metal oxinitride material; and
forming at least one electrically conductive filament in the storage region by applying a first current or voltage pulse to the storage region.

26. The method of claim 25, wherein forming at least one electrically conductive filament comprises thermally or electrically breaking metal-oxide bonds and forming metal-nitride bonds.

27. The method of claim 25, wherein applying the first current or voltage pulse comprises applying a current compliance for the pulse applied to the storage region.

28. The method of claim 25, wherein applying the first current or voltage pulse to the storage region comprises applying the first current or voltage pulse via at least one first electrode and at least one second electrode that are electrically connected to the storage region, and wherein forming the at least one electrically conductive filament comprises forming the electrically conductive filament so as to substantially extend from the first electrode to the second electrode.

29. The method of claim 28, wherein forming the at least one electrically conductive filament decreases the electrical resistance of the storage region between the first and the second electrode by a factor of at least 10.

30. The method of claim 25, further comprising reducing the electrical conductance of the electrically conducting filament by applying a second current or voltage pulse to the storage region.

31. The method of claim 30, wherein reducing the electrical conductance of the electrically conducting filament comprises thermally or electrically breaking metal-nitride bonds in the electrically conducting filament through the application of the second current of voltage pulse.

32. The method of claim 30, wherein the second current or voltage pulse supplies more energy to the storage region than the first current or voltage pulse.

33. The method of claim 30, wherein reducing the electrical conductance of the electrically conducting filament increases the electrical resistance of the storage region between a first and a second electrode connected to the storage region by a factor of at least 10.
